(19) United States
(12) Patent Application Publication
(10) Pub. No.: US 2009/0250246 A1
(43) Pub. Date: Oct. 8, 2009

(54) SOLDER BY NUMBERS, A METHOD AND SYSTEM FOR POPULATING PRINTED CIRCUIT BOARDS

(76) Inventors: Andrew Yaung, Fremont, CA (US); Neal S. Greenberg, Fremont, CA (US)

Correspondence Address: SCHNECK & SCHNECK, P.O. BOX 2-E, SAN JOSE, CA, 95109-0005, US

(21) Appl. No.: 12/099,056

(22) Filed: Apr. 7, 2008

(51) Int. Cl. H05K 1/00

(52) U.S. Cl. 174/250; 361/748; 361/760

(57) ABSTRACT

An electronic circuit assembly comprises a printed circuit board including a plurality of electrically-conductive traces disposed on at least one face of the printed circuit board and a circuit schematic layout. The plurality of electrically-conductive traces is configured to mount and electrically couple a plurality of types of electronic devices. The circuit schematic layout includes a map arranged similarly to the layout of the plurality of electrically-conductive traces disposed on the at least one face of the printed circuit board. A plurality of layout column markers and a plurality of layout row markers and a plurality of color-coded regions are marked directly onto the map. Each color of the plurality of color-coded regions is indicative of a particular one of the plurality of types of electronic devices.

### TECHNICAL FIELD

The present invention relates generally to printed circuit boards, and more particularly, to a system and method of mapping and verifying component placement on a printed circuit board.

### BACKGROUND

Printed circuit boards (PCBs) are a fundamental element in most modern electronic devices. A PCB is used to mechanically support and electrically connect electronic components using conductive pathways, or traces, etched from copper sheets laminated onto a non-conductive substrate. At specified locations on the conductive traces, copper lands, or connection mounting pads, are exposed allowing attachment of electronic devices such as integrated circuits and discrete electronic components such as inductors, capacitors, and resistors.

To attach an electronic device to the circuit board, the electronic device must be positioned such that a conductive means (e.g., a ball, pin, lead, or other terminal) from the component may be connected to the copper land. The terminal of the component is then soldered to a series of copper lands fabricated onto a surface of the PCB. In through-hole construction, component leads are inserted in holes. In surface-mount construction, the components are placed on pads or lands on the outer surfaces of the PCB. In both types of construction, component leads are electrically and mechanically fixed to the board with molten metallic solder.

Commonly, components are soldered onto the lands on a PCB either by hand or by an automated machine. In either case care must be taken. The integrated circuit or other electronic component must be properly aligned with the correct contacts to function properly. In addition, if the solder is not properly applied, it can either make improper electrical contact or, conversely, make contact between mounting pads, thus creating electrical shorts that would adversely affect the functioning of the PCB.

Generally, three problems impede a user's ability to hand solder surface mount components onto a board. First, the user must place and hold the component in place. Many of the component devices are quite small, and must be precisely positioned on pitches having small traces (e.g., a 0.4 mm pitch). The trend has been for increasingly small circuits and electronic components, thus exasperating the problem. Secondly, after positioning the component, the user must be able to solder the component into a specific location without creating short circuits to traces. Thirdly, simply locating components in the proper location is often tedious, time-consuming, and error-prone. Especially for hobbyists, there simply is no easy way to know where to place the components.

Ideally, a soldering solution would be adaptable to both aid in prototyping and hand soldering by reducing time and skill level required, and provide a solution for manufacturing processes requiring attachment of components to boards.

In many applications in which components are assembled onto PCBs, the boards are frequently monitored at a particular stage or stages in order to determine whether the assembly process is being performed properly. Specifically, the correct placement of the various components attached to a PCB should be verified in order to guard against common assembly problems before the entire assembly process is completed. Common assembly problems include missing and misplaced components. For example, the orientation of a component could be incorrect or reversed. Placement is particularly problematic for components that are sensitive to polarity, such as diodes and electrolytic capacitors. In addition, a component could be mounted askew on the mounting pad, causing it to perform unreliably or not at all.

One way of verifying the correct assembly of components is through the use of a functional test. To conduct a functional test, a PCB is completely assembled and then hooked to testing equipment to check whether it performs as expected. However, since a board must be completely assembled before it is checked, the use of this test can be wasteful if the board fails because of a defect occurring early in the assembly process. Further, programming the testing equipment is often time and labor intensive, making it difficult to reconfigure to test different types of PCBs. In addition, the initial expense of the required testing equipment is typically quite high.

With reference to FIG. 1, another prior art approach uses an overlay 100 to verify component placement. The overlay 100 consists of a positioning plate 101 in which outlines 103 of the individual components are cut out. The overlay 100 may be used to quickly verify the location, placement, and proper orientation of surface mount components on the PCB.

In FIG. 1B, a portion on of an overlay 151 confirms placement of a component 153 having solderable leads 155. Thus, the overlay 151 may be configured to fit over an assembled PCB such that individual components project into corresponding holes. An operator may quickly scan the overlay to verify the correct placement of components on the PCB.

However, verification using overlay devices requires the user to physically handle the circuit boards to be tested, thereby exposing the boards to the risk of damage from static discharge if the overlays are made of static harboring materials such as phenolic resin or fiberglass. Similarly, there is a risk of electrical discharge with overlays made of conductive materials such as stainless steel. Stainless steel overlays are also fairly heavy, expensive to fabricate, and may have sharp edges that could cut the operator.

Therefore, what is needed is a reliable system that readily aids in the proper placement of components onto a PCB. Further, the system should make hand soldering of even small-pitched components simple and electrically robust even by one inexperienced at soldering.

### SUMMARY

In an exemplary embodiment, an electronic circuit assembly system is disclosed. The electronic circuit assembly comprises a printed circuit board including a plurality of electrically-conductive traces disposed on at least one face of the printed circuit board and a circuit schematic layout. The plurality of electrically-conductive traces is configured to mount and electrically couple a plurality of types of electronic devices. The circuit schematic layout includes a map arranged similarly to the layout of the plurality of electrically-conductive traces disposed on the at least one face of the printed circuit board. A plurality of layout column markers, a plurality of layout row markers, and a plurality of color-coded regions are marked directly onto the map. Each of the plurality of color-coded regions is indicative of a particular one of the plurality of types of electronic devices.

In another exemplary embodiment, an electronic circuit assembly system is disclosed which comprises a printed circuit board and a circuit schematic layout. The printed circuit board includes a plurality of electrically-conductive traces disposed on at least one face of the printed circuit board which are configured to mount, solder, and electrically couple a plurality of electronic components. The printed circuit board further includes a plurality of printed circuit board column markers and a plurality of printed circuit board row markers. The circuit schematic layout includes a map arranged similarly to the layout of the plurality of electrically-conductive traces disposed on the at least one face of the printed circuit board, a plurality of layout column markers, and a plurality of layout row markers corresponding to the plurality of printed circuit board column markers and the plurality of printed circuit board row markers. A polarity indicator is located on the circuit schematic layout for particular ones of the plurality of electronic components and a plurality of color-coded regions are marked directly onto the map. Each of the plurality of color-coded regions is indicative of a particular one of the plurality of electronic components.

In another exemplary embodiment, a method of populating a printed circuit board is disclosed. The method comprises selecting a first electronic component type, identifying a color associated with the first electronic component type on a circuit layout map, selecting a component from the first electronic component type, locating the component on the circuit layout map by matching both the color and a descriptor of the component, and noting any polarity indications on the circuit layout map associated with the component. A set of circuit layout map grid coordinates associated with the component is identified and matched to a set of grid coordinates on the printed circuit board corresponding to the set of circuit layout map grid coordinates. The component is placed at the location identified by the set of grid coordinates on the printed circuit board and soldered to the printed circuit board.

### BRIEF DESCRIPTION OF THE DRAWINGS

The appended drawings illustrate exemplary embodiments of the present invention and must not be considered as limiting its scope.

FIG. 1A is an overlay of the prior art used to verify proper component placement on a printed circuit board.

FIG. 1B is a portion of an overlay of the prior art in use over components on a printed circuit board.

FIG. 2 is an exemplary circuit schematic layout in accord with various embodiments of the present invention.

FIG. 3 is an exemplary printed circuit board to physically mount electronic components as mapped by the circuit schematic layout of FIG. 2.

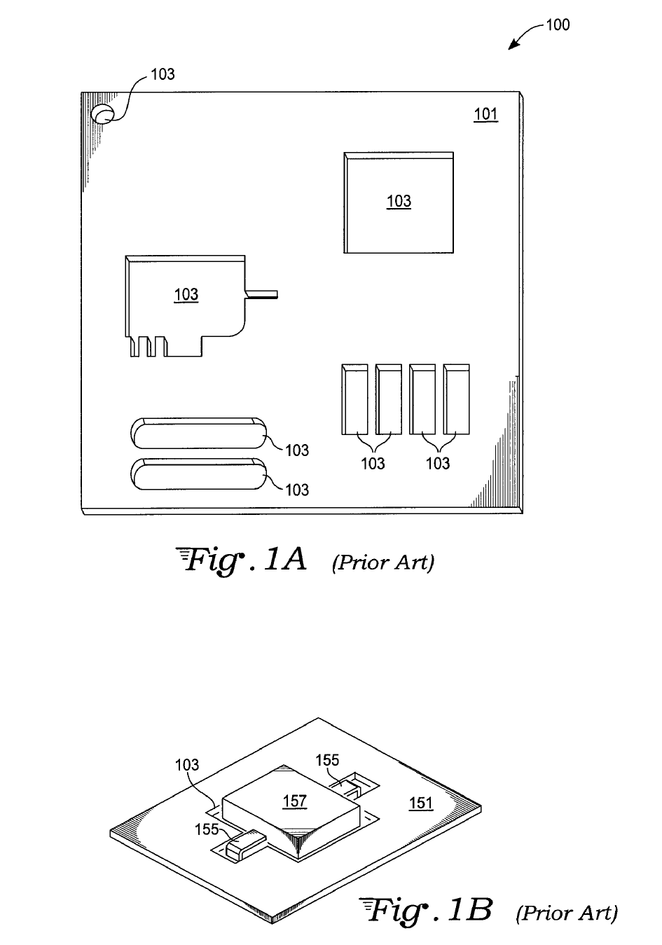

### DETAILED DESCRIPTION

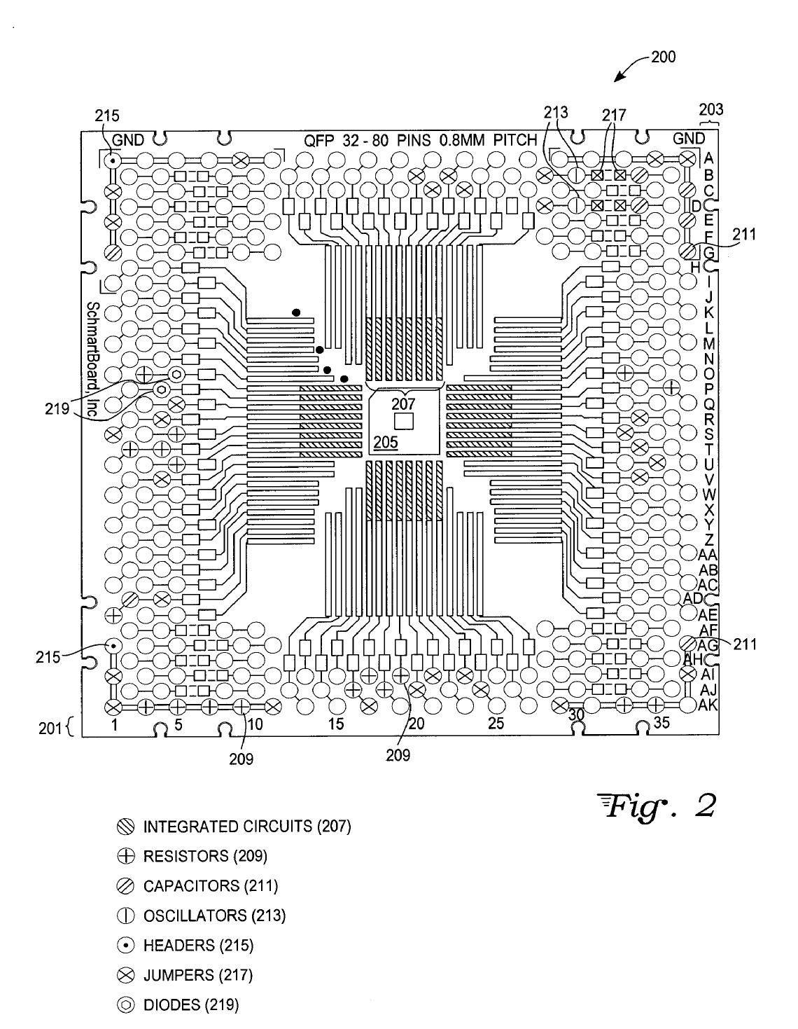

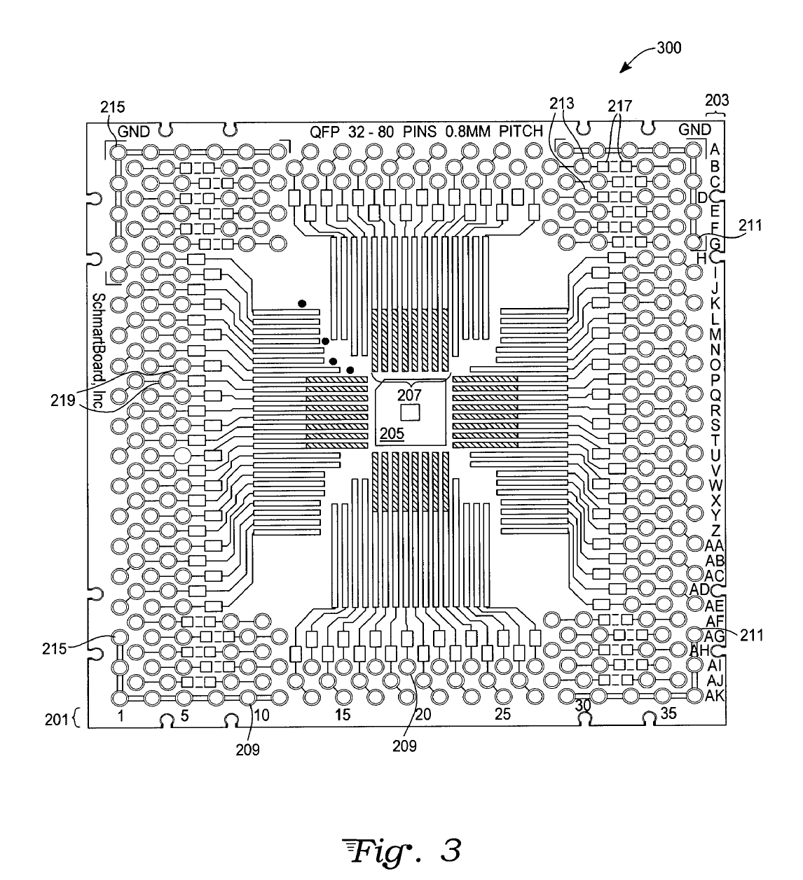

Various exemplary embodiments shown and described herein illustrate a circuit schematic layout that indicates, or maps, exactly where a given electronic component should be placed and soldered onto an accompanying printed circuit board (PCB) for a particular circuit. (Thus, each particular circuit has a circuit schematic layout and accompanying PCB.) The circuit schematic layout has a map similar to that of the circuit arranged on the PCB. Various colors of indicators (colors are indicated herein by various types of hatching in FIGS. 2 and 3, as described below) are indicated on the map to quickly indicate where all leads of each component are to be mounted on the accompanying PCB. Also, the circuit schematic layout provides a proper component orientation where appropriate (e.g., indicating the proper orientation of polarities for an electrolytic capacitor or the placement of pin I on an integrated circuit). The PCB has appropriate through-holes, surface mount lands, or other appropriate solder areas on to which to mount each type of component.

With reference simultaneously to FIGS. 2 and 3, an exemplary circuit schematic layout 200 includes both column markers 201 and row markers 203. In this embodiment, the column markers 201 are marked at intervals of 5 along the lower edge of the circuit schematic layout 200. The row markers 203 are marked as “A” through “AK.” As a result of the map-like or grid-coordinate markers, any lead of a component (not shown) may be quickly located on an accompanying PCB 300 (FIG. 3). For example, a positive terminal of a capacitor (i.e., capacitor C1), is located at coordinate “B-34” (i.e., row “B” and column “34”). Although shown in FIG. 3, the accompanying PCB 300 may not have a corresponding set of row and column markers, since such markers on the PCB 300 are not necessary for proper implementation of the embodiments described herein.

An integrated circuit mark 205 is located at the center of the circuit schematic layout 200. The integrated circuit mark 205 has a chamfered corner located on the upper left to indicate pin 1 of an associated integrated circuit (not shown). A plurality of integrated circuit bonding pads 207 are clearly marked in a first color (indicated in FIG. 2 by shading) to quickly indicate where each of the pins of the integrated circuit are to be located and soldered. As noted in FIG. 2, only a portion of the integrated circuit bonding pads are labeled directly to avoid obscuring the drawing. However, a skilled artisan will quickly realize the integrated circuit bonding pads are located around the entire periphery of the integrated circuit mark 205 as indicated in the legend.

FIG. 2 further indicates a plurality of resistor bonding pads. The resistor bonding pads are indicated by a second hatch marking (indicative of a second color on the actual schematic layout). For example, resistor R₃ (not shown) will be physically mounted and soldered on the accompanying PCB 300 with leads placed at positions R₃ 209 at locations “AK-9” and “AI-19,” respectively. Further, each of the other resistors required for the circuit (i.e., resistors R₁, R₂, R₄, . . . R₁₀ for the exemplary embodiment shown in FIG. 2) are labeled on the circuit schematic layout 200.

Similarly, a plurality of capacitor bonding pads for the required capacitors (i.e., capacitors C₁, C₂, . . . C₄) and a single pair of oscillator pads for the crystal oscillator (i.e., oscillator X₁), are indicated, each with a respective hatching indicative of a third and fourth color on the actual schematic layout. Capacitor C₄ (not shown) is mounted at positions C₄ 211 on the accompanying PCB 300. However, unlike resistors which are non-polarity specific, the positive lead of capacitor C₄ is mounted and soldered to C₄+ 211 at location “AG-37” while the negative lead is mounted and soldered to C₄− 211 at location “G-37.” Thus, when required, polarity information needed for certain types of electronic components are clearly labeled on the circuit schematic layout 200. The non-polarity specific oscillator (not shown) is mounted and soldered to X₁ 213 at locations “B-30” and “D-30.” Locations for the capacitors and the oscillator are indicated by a third and fourth color, respectively.

A plurality of header bonding pads, indicated by a fifth color, to correspond to pin numbering on a required header are indicated at H₁ 215 at coordinate location “A-1” and H₂ 215 at coordinate location “AG-1.” The circuit schematic layout 200 also includes a large number of non-polarity specific jumper bonding pads indicated by a sixth color. For example, one jumper is mounted and soldered to positions J₇₀ 217 at locations “B-31” and B-32.”

The final electronic device component type indicated by the circuit schematic layout 200 is a single diode, D₁ indicated by a seventh color. The diode is mounted and soldered to the accompanying PCB 300 with the positive lead at position 219 at location “O-5” and the negative lead is connected to position 219 at “P-4.”

In other exemplary embodiments (not shown), additional electronic components would be paired with respective colors on an appropriate circuit schematic layout and supporting legend. Since all components are mapped by both color and a grid-mapping type system (i.e., a grid coordinate), component placement on an accompanying PCB may be readily and properly accomplished by nearly anyone with even an extremely modest understanding of electronics.

The present invention is described above with reference to specific embodiments thereof. It will, however, be evident to a skilled artisan that various modifications and changes can be made thereto without departing from the broader spirit and scope of the present invention as set forth in the appended claims. For example, although described herein with reference to a relatively simple schematic, more complex circuits are amenable to the same circuit schematic layout and PCB combination as well. A skilled artisan will further recognize that various numbers of individual PCBs may all be assembled in accordance with the present invention and the individual boards may then be appropriately interconnected for much more complex circuits. Further, individual PCBs may be color-coded, along with color-coded interconnection tabs, so as to combine boards in various configurations to produce more complex circuits. Also, the map may be readily designed to be used as an overlay itself along with various embodiments described herein. These and various other embodiments are all within a scope of the present invention and would be readily understood by a skilled practitioner. The specification and drawings are, accordingly, to be regarded in an illustrative rather than a restrictive sense.

What is claimed is:

1. An electronic circuit assembly system, comprising:
a printed circuit board including a plurality of electrically-conductive traces disposed on at least one face of the printed circuit board, the plurality of electrically-conductive traces configured to mount and electrically couple a plurality of types of electronic devices; and
a circuit schematic layout including:
a map of the layout of the plurality of electrically-conductive traces disposed on the at least one face of the printed circuit board, the map arranged similarly to the printed circuit board;
a plurality of layout column markers and a plurality of layout row markers; and
a plurality of color-coded regions marked directly onto the map, each color of the plurality of color-coded regions being indicative of a particular one of the plurality of types of electronic devices.

2. The electronic circuit assembly system of claim 1 wherein the plurality of layout column markers and the plurality of layout row markers are located at adjoining edges of the circuit schematic layout.

3. The electronic circuit assembly system of claim 1 further comprising a plurality of printed circuit board column markers and a plurality of printed circuit board row markers on the printed circuit board corresponding to the plurality of layout column markers and the plurality of layout row markers.

4. The electronic circuit assembly system of claim 3 wherein the plurality of printed circuit board column markers and the plurality of printed circuit board row markers are located at adjoining edges of the printed circuit board.

5. The electronic circuit assembly system of claim 1 further comprising a plurality of through holes in the printed circuit board configured to accommodate lead wires on certain types of the electronic devices.

6. The electronic circuit assembly system of claim 1 further comprising a plurality of bond pads on the printed circuit board configured to accommodate integrated circuit devices.

7. The electronic circuit assembly system of claim 1 wherein the circuit schematic layout further comprises an indication of polarity for particular ones of the plurality of types of electronic devices.

8. The electronic circuit assembly system of claim 1 wherein the circuit schematic layout further comprises an indication of a “pin 1” indicator for integrated circuits.

9. The electronic circuit assembly system of claim 1 wherein the circuit schematic layout further comprises an indication of device type for each of the particular ones of the plurality of types of electronic devices.

10. The electronic circuit assembly system of claim 1 wherein the circuit schematic layout further comprises a color-coded legend to correspond with the plurality of color-coded regions marked directly onto the map.

11. An electronic circuit assembly system, comprising:
a printed circuit board including:
a plurality of electrically-conductive traces disposed on at least one face of the printed circuit board, the plurality of electrically-conductive traces configured to mount, solder, and electrically couple a plurality of electronic components; and
a plurality of printed circuit board column markers and a plurality of printed circuit board row markers;
a circuit schematic layout including:
a map of the layout of the plurality of electrically-conductive traces it disposed on the at least one face of the printed circuit board, the map arranged similarly to the printed circuit board and having a plurality of color-coded regions marked directly onto the map, each of the plurality of color-coded regions being indicative of a particular one of the plurality of electronic components;
a plurality of layout column markers and a plurality of layout row markers corresponding to the plurality of printed circuit board column markers and the plurality of printed circuit board row markers; and
a polarity indicator for particular ones of the plurality of electronic components.

12. The electronic circuit assembly system of claim 11 wherein the plurality of layout column markers and the plurality of layout row markers are located at adjoining edges of the circuit schematic layout.

13. The electronic circuit assembly system of claim 11 wherein the plurality of printed circuit board column markers and the plurality of printed circuit board row markers are located at adjoining edges of the printed circuit board.

14. The electronic circuit assembly system of claim 11 further comprising a plurality of through holes in the printed circuit board configured to accommodate lead wires on certain types of the electronic components.

15. The electronic circuit assembly system of claim 11 further comprising a plurality of bond pads on the printed circuit board configured to accommodate integrated circuit devices.

16. The electronic circuit assembly system of claim 11 wherein the circuit schematic layout further comprises an indication of device type for each of the particular ones of the plurality of electronic components.

17. The electronic circuit assembly system of claim 11 wherein the circuit schematic layout further comprises an indication of a “pin 1” indicator for integrated circuits.

18. The electronic circuit assembly system of claim 11 wherein the circuit schematic layout further comprises a color-coded legend to correspond with the plurality of color-coded regions marked directly onto the map.

19. A method of populating a printed circuit board, the method comprising: selecting a first electronic component type;
identifying a color associated with the first electronic component type on a circuit layout map;
selecting a component from the first electronic component type;
locating the component on the circuit layout map by matching both the color and a descriptor of the component;
noting any polarity indications on the circuit layout map associated with the component;
identifying a set of circuit layout map grid coordinates associated with the component;
identifying a set of grid coordinates on the printed circuit board corresponding to the set of circuit layout map grid coordinates;
placing the component at a location associated with the set of grid coordinates on the printed circuit board; and
soldering the component to the printed circuit board.

20. The method of claim 19 further comprising repeating the steps for each component associated with each of the electronic component types to be mounted on the printed circuit board.
